(19) United States
(12) Patent Application Publication
(10) Pub. No.: US 2016/0217870 A1
(43) Pub. Date: Jul. 28, 2016

(54) SHIFT REGISTER UNIT, GATE DRIVE CIRCUIT AND DISPLAY PANEL

(71) Applicant: EverDisplay Optronics (Shanghai) Limited, Shanghai City (CN)

(72) Inventors: Ying-Hsiang Tseng, Shanghai City (CN); Lina Xiao, Shanghai City (CN)

(21) Appl. No.: 15/004,046

(22) Filed: Jan. 22, 2016

(30) Foreign Application Priority Data
Jan. 26, 2015 (CN) 201510039543.9

(51) Int. Cl. G11C 19/28; G09G 3/32

(52) U.S. Cl. CPC G11C 19/28; G09G 3/3225; G09G 2300/0809; G09G 2310/0286

(57) ABSTRACT

Provided are a shift register unit, a gate drive circuit, and a display panel. The shift register unit includes a first to sixth transistor and a first and second capacitor.

This application is based upon and claims priority to Chinese Patent Application No. 201510039543.9, filed on Jan. 26, 2015, the entire contents of which are incorporated herein by reference.

### TECHNICAL FIELD

The present disclosure relates to a field of display technology, and more particularly, to a shift register unit, a gate drive circuit applying the shift register unit and a display panel applying the gate drive circuit.

### BACKGROUND

Compared with liquid crystal display panel in the conventional technology, OLED (Organic Light Emitting Diode) display panel has characteristics of faster response, better color purity and brightness, higher contrast, wider visual angle and so on. Therefore, display technology developers are paying increasingly widespread attention to it. However, it is still to be improved for the OLED display panel in the related art.

For example, the display of the OLED display panel is mainly realized by pixel matrix. Generally speaking, pixels of each row are coupled to the corresponding scan gate lines. During the operating process of the OLED display panel, the input signals are converted to on/off control signals via the conversion of the shift register unit by the gate drive circuit, and then applied to the scan gate lines of pixels of each row of the OLED display panels, thereby strobing the pixels of each row.

However, the shift register unit in the related art usually includes many transistors, and requires many clock signals to drive. With the development of the flat panel display technology, products with high resolution and narrow frame have been paid more and more attention. The large amount of transistors in the shift register unit in the related art will occupy large wiring area, which is disadvantageous to the increasing of effective display area and the narrow frame design; in addition, more transistors increase the preparation process difficulty of the shift register unit, and increase the preparation cost.

### SUMMARY

The other characteristics and advantages of the present disclosure will become apparent from the following description, or in part, may be learned by the practice of the present disclosure.

According to the first aspect of the present disclosure, there is provided a shift register unit, including: a first to sixth transistor and a first and second capacitor; wherein: a control end and a first end of the first transistor are coupled with a signal input end, and a second end of the first transistor is coupled with a first node; a control end of the second transistor is coupled with a first clock signal, a first end of the second transistor is coupled with a first voltage, and a second end of the second transistor is coupled with the first node; a control end of the third transistor is coupled with the first node, a first end of the third transistor is coupled with the first voltage, and a second end of the third transistor is coupled with a second node; a control end of the fourth transistor is coupled with the first clock signal, a first end of the fourth transistor is coupled with a second voltage, and a second end of the fourth transistor is coupled with the second node; a control end of the fifth transistor is coupled with the second node, a first end of the fifth transistor is coupled with the first voltage, and a second end of the fifth transistor is coupled with a signal output end; a control end of the sixth transistor is coupled with a first end of the second capacitor, a first end of the sixth transistor is coupled with a second clock signal, and a second end of the sixth transistor is coupled with the signal output end; a first end of the first capacitor is coupled with the first voltage, and a second end of the first capacitor is coupled with the second node; and the first end of the second capacitor is coupled with the first node, and a second end of the second capacitor is coupled with the signal output end.

According to the second aspect of the present disclosure, there is provided a gate drive circuit, the gate drive circuit including any one of the above shift register units.

According to the third aspect of the present disclosure, there is provided a display panel, including any one of the gate drive circuits above.

### BRIEF DESCRIPTION OF THE DRAWINGS

The exemplary embodiments of the disclosure will be described in detail with reference to the accompanying drawings, through which the above and other features and advantages of the disclosure will become more apparent.

FIG. 1 is a structural schematic diagram of a shift register unit in the exemplary embodiments of the present invention.

FIG. 2 is a structural schematic diagram of another shift register unit in the exemplary embodiments of the present invention

FIG. 3 is a schematic diagram of the driving timing and signal waveform of the shift register units in FIG. 1 and FIG. 2.

FIGS. 4-9 are equivalent circuit diagrams in t1-t6 timing segments of the shift register unit in FIG. 2.

FIG. 10 is an implementation structural schematic diagram of the gate drive circuit in the exemplary embodiments of the present invention.

FIG. 11 is a schematic diagram of output signals of the gate drive circuit in FIG. 10.

### DESCRIPTION OF THE EMBODIMENTS

The exemplary embodiments will now be described more fully with reference to the accompanying drawings. However, the exemplary embodiments can be implemented in various forms and should not be understood as being limited to the embodiments set forth herein; on the contrary, these embodiments are provided so that this disclosure will be thorough and complete, and the concept of exemplary embodiments will be fully conveyed to those skilled in the art. In the drawings, the thicknesses of the regions and layers are exaggerated for clarity. In the drawings, the same reference numerals denote the same or similar structure, thus their detailed description will be omitted.

In addition, the described features, structures, or characteristics may be combined in one or more embodiments in any suitable manner. In the following description, numerous specific details are provided so as to allow a full understanding of the embodiments of the present disclosure. However, those skilled in the art will recognize that the technical solutions of the present disclosure may be practiced without one or more of the specific details, or other methods, components, materials and so on may be used. In other cases, the well-known structures, materials or operations are not shown or described in detail to avoid obscuring various aspects of the present disclosure.

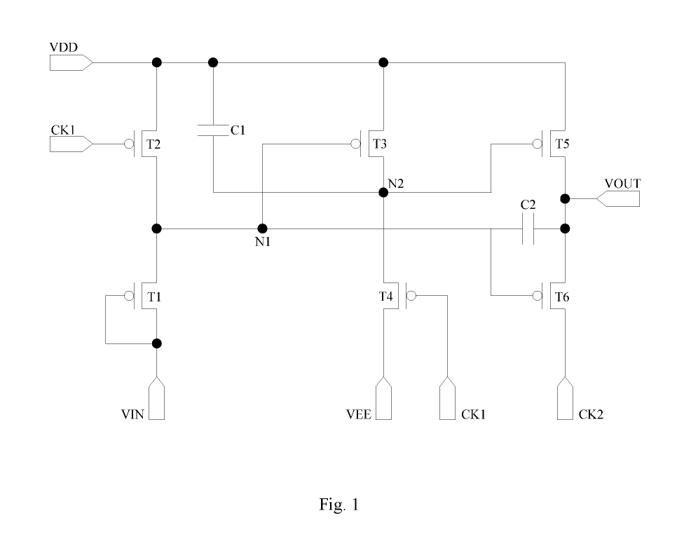

As shown in FIG. 1, a shift register unit is firstly provided in the present exemplary embodiment. It includes a first transistor T1, a second transistor T2, a third transistor T3, a fourth transistor T4, a fifth transistor T5, a sixth transistor T6, and a first capacitor C1 and a second capacitor C2. The first to sixth transistor being all P-type transistors is taken as an example to illustrate in the present exemplary embodiment. The circuit structure of the shift register unit may be as follows.

A control end and a first end of the first transistor T1 are coupled with a signal input end VIN, a second end of the first transistor T1 is coupled with a first node N1. When the signal input by the signal input end VIN is a low level, the first transistor T1 turns on, and the signal input by the signal input end VIN is input to the first node N1.

A control end of the second transistor T2 is coupled with a first clock signal CK1, and a first end of the second transistor T2 is coupled with a first voltage VDD. In the present exemplary embodiment, the first voltage VDD is a high level voltage. A second end of the second transistor T2 is coupled with the first node N1. When the first clock signal CK1 is a low level, the second transistor T2 turns on, and the first voltage VDD is input to the first node N1.

A control end of the third transistor T3 is coupled with the first node N1, a first end of the third transistor T3 is coupled with the first voltage VDD, and a second end of the third transistor T3 is coupled with the second node N2. When the potential of the first node N1 is a low level, the third transistor T3 turns on, and the first voltage VDD is input to the second node N2.

A control end of the fourth transistor T4 is coupled with the first clock signal CK1, and a first end of the fourth transistor T4 is coupled with the second voltage VEE. In the present exemplary embodiment, the second voltage VEE is a low level voltage. A second end of the fourth transistor T4 is coupled with the second node N2. When the first clock signal CK1 is a low level, the fourth transistor T4 turns on, and the second voltage VEE is input to the second node N2.

A control end of the fifth transistor T5 is coupled with the second node N2, a first end of the fifth transistor T5 is coupled with the first voltage VDD, and a second end of the fifth transistor T5 is coupled with a signal output end VOUT. When the potential of the second node N2 is a low level, the fifth transistor T5 turns on, and the first voltage VDD is output from the signal output end VOUT. Because the first voltage VDD is a high level voltage in the present exemplary embodiment, when the potential of the second node N2 is a low level, the shift register unit may output a high level signal.

A control end of the sixth transistor T6 is coupled with a first end of the second capacitor C2, a first end of the sixth transistor T6 is coupled with a second clock signal CK2, and a second end of the sixth transistor T6 is coupled with the signal output end VOUT. When the voltage of the first end of the second capacitor C2 is a low level, the sixth transistor T6 turns on, and the second clock signal CK2 is output from the signal output end VOUT. Therefore, when the sixth transistor T6 turns on, if the second clock signal CK2 is in a high level, the shift register unit outputs a high level signal, and if the second clock signal CK2 is in a low level, the shift register unit outputs a low level signal.

A first end of the first capacitor C1 is coupled with the first voltage VDD, and a second end of the first capacitor C1 is coupled with the second node N2. The first capacitor C1 is used to store the voltage of the second node N2. The first end of the second capacitor C2 is coupled with the first node N1, and a second end of the second capacitor C2 is coupled with the signal output end VOUT. The second capacitor C2 is used to store the voltage of the first node N1.

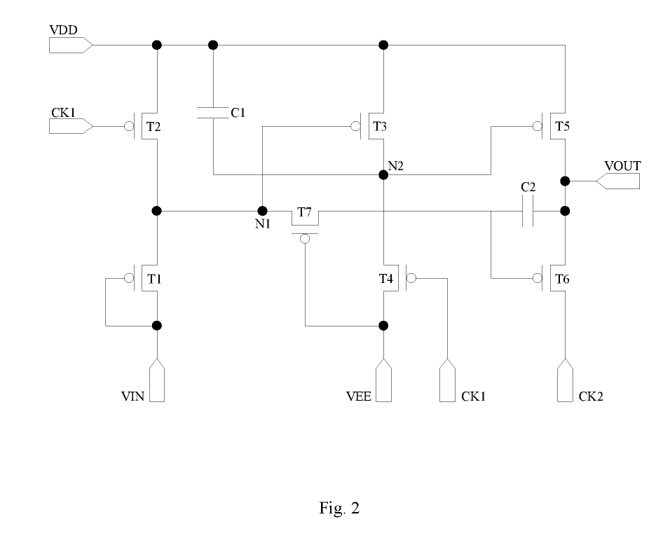

As shown in FIG. 2, in an exemplary embodiment of the present disclosure, the shift register unit may further include a seventh transistor T7, the second capacitor C2 is coupled with the first node N1 via the seventh transistor T7. A control end of the seventh transistor T7 is coupled with the second voltage VEE, a first end of the seventh transistor T7 is coupled with the first node N1, and a second end of the seventh transistor T7 is coupled with the first end of the second capacitor C2.

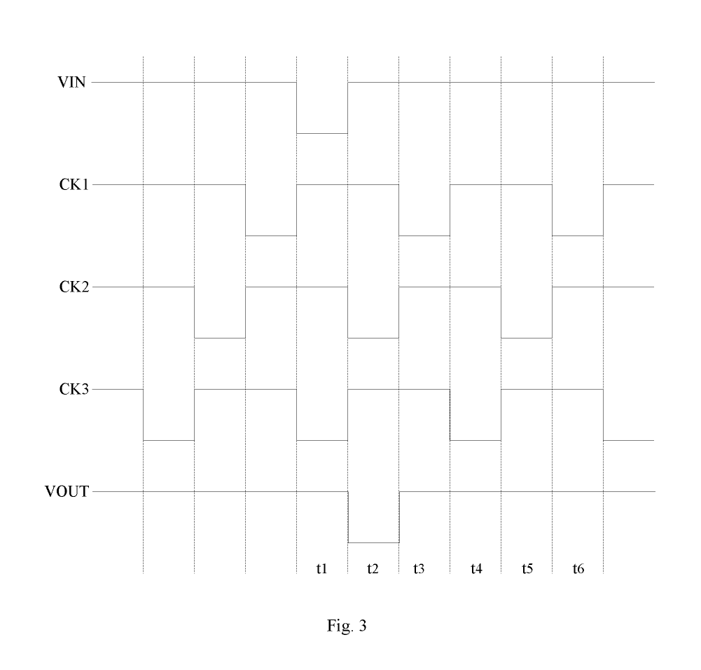

The operating principle of the shift register unit in the present exemplary embodiment is illustrated more detailedly in combination with the driving timing diagram as shown in FIG. 3 below. Referring to FIG. 3, in the present exemplary embodiment, a phase of the first clock signal CK1 is ahead of the second clock signal CK2 by ⅔ of a signal period. The duty cycles of the low level of the first clock signal CK1 and the second clock signal CK2 are both 1:3. The operating process of the shift register may include the following stages.

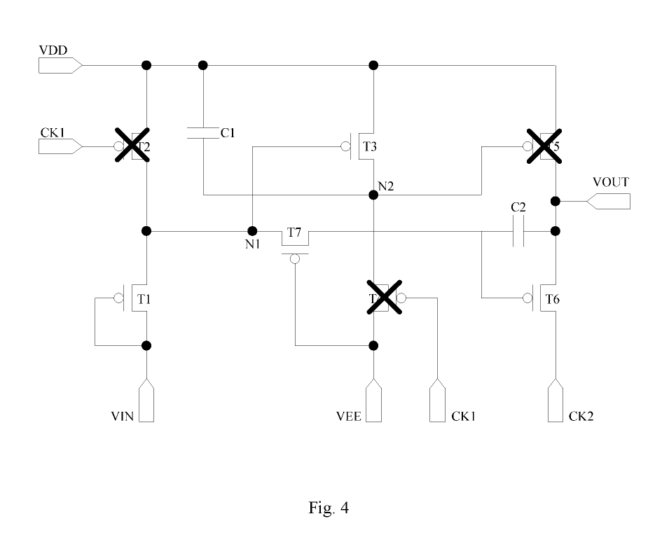

Referring to FIG. 3 and FIG. 4, during charging stage t1, the first clock signal CK1 and the second clock signal CK2 are high levels, and the signal input by the signal input end VIN is a low level. The first transistor T1 is turned on, and the second transistor T2 and the fourth transistor T4 are turned off. The signal input by the signal input end VIN is input to the first node N1 via the first transistor T1, thus charging the second capacitor C2, and turning on the third transistor T3 and the sixth transistor T6 at the same time. The first voltage VDD is input to the second node N2 via the third transistor T3, thus turning off the fifth transistor T5. The second clock signal CK2 is output from the signal output end VOUT via the sixth transistor T6. Because the second clock signal CK2 is a high level in this stage, the shift register unit also outputs a high level signal.

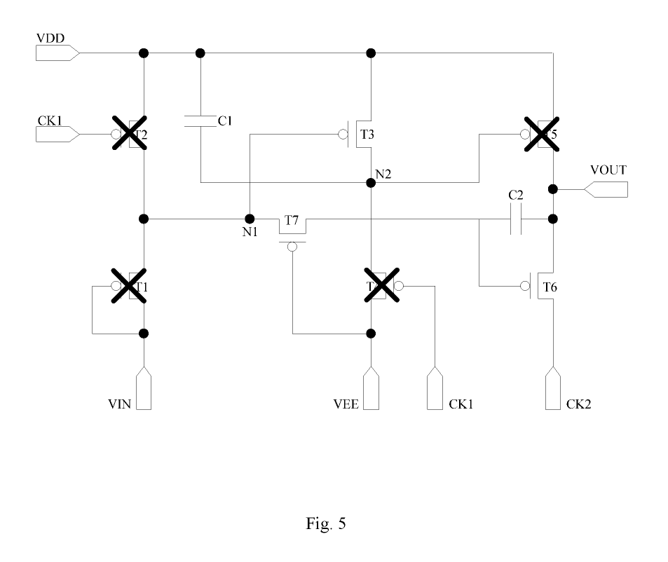

Referring to FIG. 3 and FIG. 5, during output stage t2, the signal input by the signal input end VIN and the first clock signal CK1 are high levels, and the second clock signal CK2 is a low level. The first transistor T1, the second transistor T2 and the fourth transistor T4 are turned off. Under the effect of the low level voltage signal stored in the second capacitor C2, the voltage of the first node N1 is still a low level, thus the third transistor T3 and the sixth transistor T6 are kept on. The first voltage VDD is input to the second node N2 via the third transistor T3, thus turning off the fifth transistor T5. The second clock signal CK2 is output from the signal output end VOUT via the sixth transistor T6. Because the second clock signal CK2 is a low level in this stage, the shift register unit also outputs a low level signal.

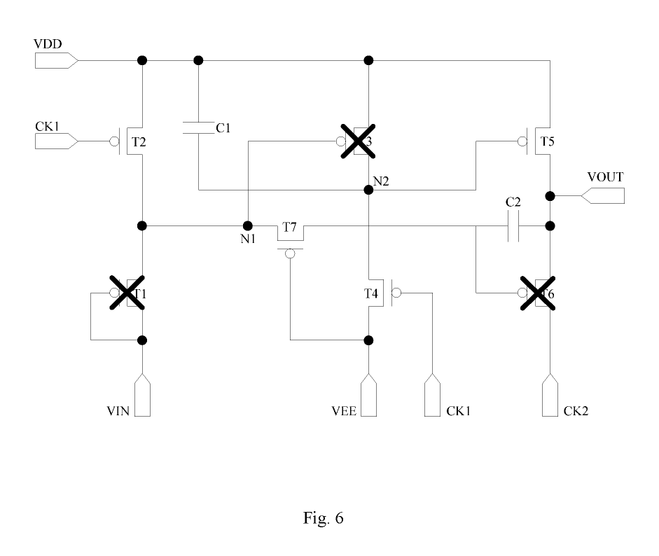

Referring to FIG. 3 and FIG. 6, during reset stage t3, the signal input by the signal input end VIN and the second clock signal CK2 are high levels, and the first clock signal CK1 is a low level. The second transistor T2 and the fourth transistor T4 are turned on, and the first transistor T1 is turned off. The first voltage VDD is input to the first node N1 via the second transistor T2, thus resetting the second capacitor C2, and the third transistor T3 and the sixth transistor T6 are turned off at the same time. The second voltage VEE is input to the second node N2 via the fourth transistor T4, thus charging the first capacitor C1, and turning on the fifth transistor T5. The first voltage VDD is output from the signal output end VOUT via the fifth transistor T5. Because the first voltage VDD is a high level, the shift register unit also outputs a high level signal.

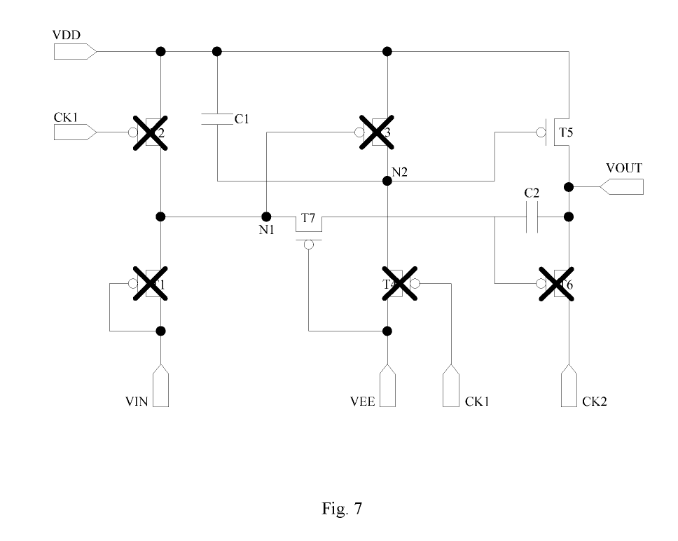

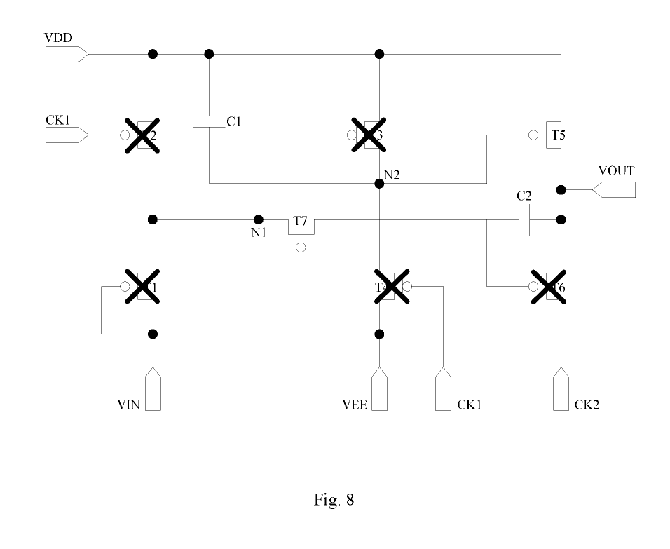

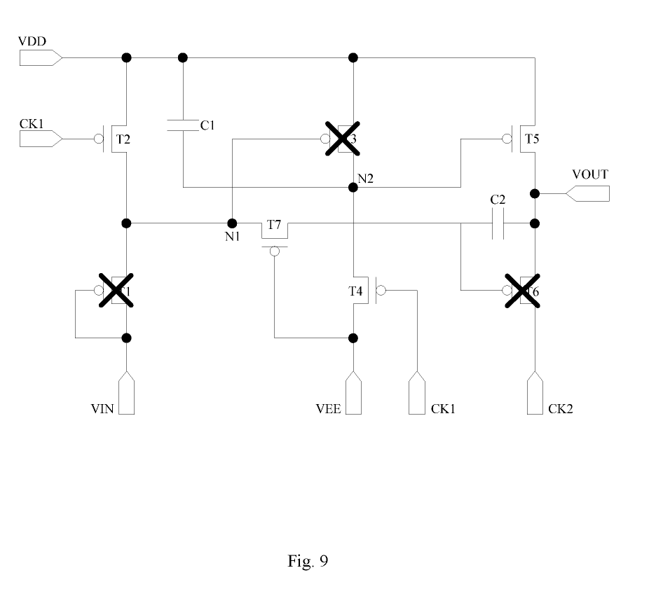

Referring to FIG. 3 and FIGS. 7-9, during stages t4-t6 after the reset stage t3, under the effect of the low level voltage signal stored in the first capacitor C1, the voltage of the second node N2 is still a low level. The fifth transistor T5 is kept on, and the first voltage VDD is output from the signal output end VOUT via the fifth transistor T5. Because the first voltage VDD is a high level, the shift register unit still outputs a high level signal. In addition, when the first clock signal CK1 is a low level, the fourth transistor T4 is turned on, and the second voltage VEE is input to the second node N2 via the fourth transistor T4, thus charging the first capacitor C1, and keeping the fifth transistor T5 on, ensuring the shift register unit to output a high level signal.

The additional advantage of the pixel driving circuit in the present embodiment is the use of a single channel type transistor, i.e., all the transistors are P-type thin film transistor. Using all P-type thin film transistors further has the following advantages, for example, a strong suppression for noise. For example, because of being turned on at low level, it is easier to achieve a low level in the charging management. For example, N-type thin film transistor is vulnerable to be affected by ground bounce, while P-type thin film transistor will only be affected by driving voltage line IR Drop, and generally the impact of IR Drop is easier to be eliminated. For example, P-type thin film transistor manufacturing process is simple, and the price is relatively low. For example, the stability of P-type thin film transistor is better and so on. Therefore, using all P-type thin film transistors may not only reduce the complexity of the preparation technology and the production cost, but also contributes to improve quality of the products. Of course, those skilled in the art may easily obtain that the shift register unit provided by the present invention may be changed to all N-type thin film transistors easily. For example, when all the transistors are N-type thin film transistors, the first voltage above is a low level voltage, the second voltage above is a high level voltage, duty cycles of the high levels of the first clock signal and the second clock signal are both 1:3. Therefore, it is not limited to the implementation provided by the present embodiment, which will not be repeatedly illustrated herein.

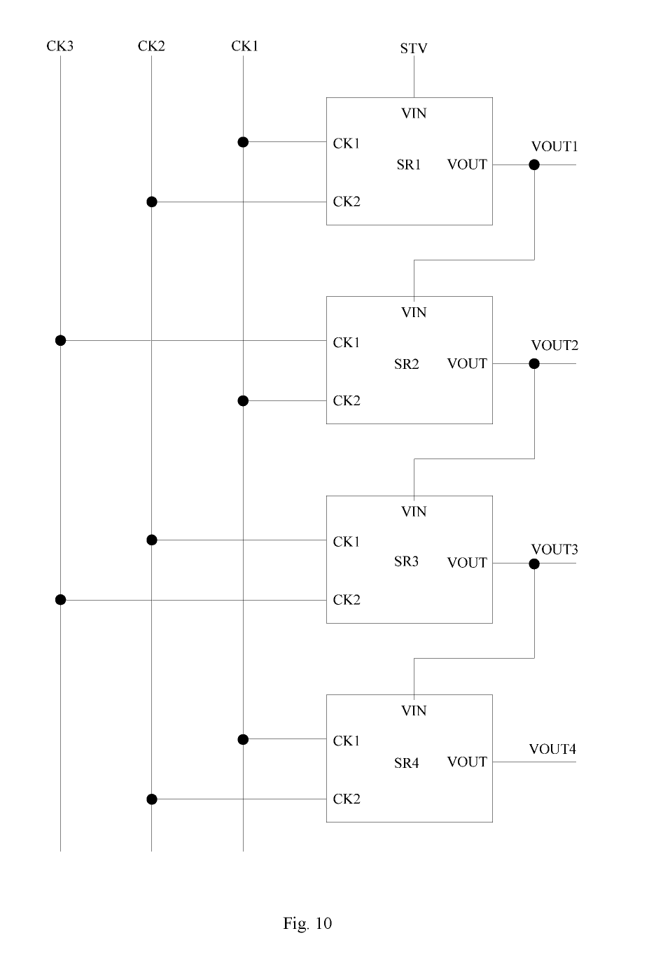

Further, the present exemplary embodiment also provides a gate drive circuit, the gate drive circuit including any one of the above shift register units. Specifically, the gate drive circuit in the present exemplary embodiment may be shown as FIG. 10, including a plurality of shift register units, such as the first shift register unit SR1, the second shift register unit SR2, the third shift register unit SR3 and the fourth shift register unit SR4. Except for the first level shift register unit, signal input ends VIN of each level shift register unit left are all coupled with signal output ends VOUT of the previous level shift register unit. Except for the last level shift register unit, signal output ends VOUT of each level shift register unit left are all coupled with signal input ends VIN of the next level shift register unit. A signal input end VIN of the first level shift register is connected with an initial signal STV. That is, as shown in the figure, a signal input end VIN of the first level shift register SR1 is connected with an initial signal STV. A signal output end VOUT of the first level shift register SR1 is coupled with a signal input end VIN of the second shift register unit SR2. A signal output end VOUT of the second shift register unit SR2 is coupled with a signal input end VIN of the third shift register unit SR3. A signal output end VOUT of the third shift register unit SR3 is coupled with a signal input end VIN of the fourth shift register unit SR4. A signal output end VOUT of the fourth shift register unit SR4 is coupled with a signal input end VIN of the next level shift register unit and so on.

Continuing to refer to FIG. 10, in an exemplary embodiment of the present disclosure, the gate drive circuit may further include a clock signal generation unit. The clock signal generation unit is used for generating a first clock signal CK1, a second clock signal CK2 and a third clock signal CK3 whose phases are different form each other by ⅔ of a signal period. A first clock signal CK1 in the first shift register unit SR1 may be the first clock signal CK1 generated by the clock signal generation unit, and a second clock signal CK2 in the first shift register unit SR1 may be the second clock signal CK2 generated by the clock signal generation unit. A first clock signal CK1 in the second shift register unit SR2 may be the third clock signal CK3 generated by the clock signal generation unit, and a second clock signal CK2 in the second shift register unit SR2 may be the first clock signal CK1 generated by the clock signal generation unit. A first clock signal CK1 in the third shift register unit SR3 may be the second clock signal CK2 generated by the clock signal generation unit, and a second clock signal CK2 in the third shift register unit SR3 may be the third clock signal CK3 generated by the clock signal generation unit.

Compared with the related art, the gate drive circuit in the present exemplary embodiment only requires three groups of clock signals, thus reducing the amount of the control signals, and saving the wiring of the control signal, more beneficial to achieve a display panel with narrower frame.

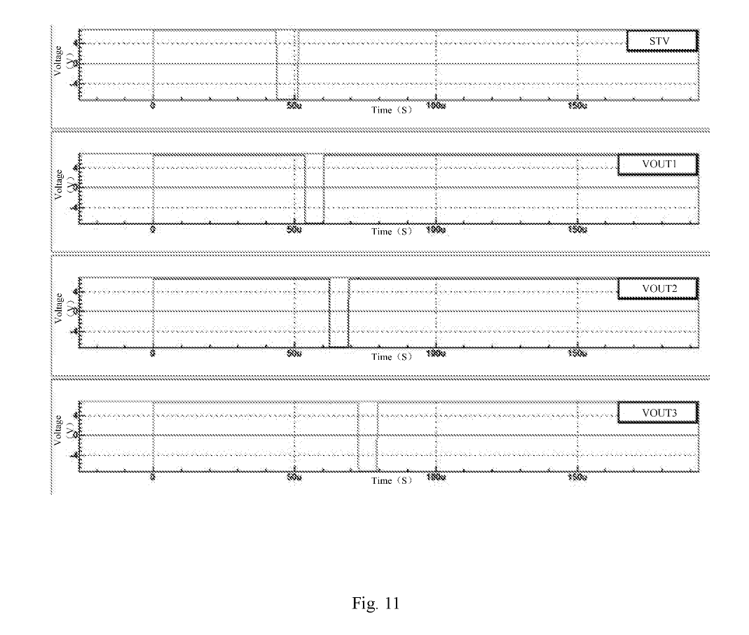

Further, the inventor also makes experimental verification on the technical effect of the gate drive circuit in the present exemplary embodiment. As shown in FIG. 11, it can be seen that the output signal waveform of the gate drive circuit in the present exemplary embodiment is effective and correct, which does not influence the performance of the gate drive circuit.

Further, the present exemplary embodiment also provides a display panel, the display panel including any one of the above gate drive circuits. Because the used the gate drive circuit has smaller wiring area, the effective display area of the display panel is increased, which is beneficial to improving the resolution of the display panel, and meanwhile, the frame of the display panel may be made narrower.

Above all, in exemplary embodiments of the present disclosure, the shift register unit is formed with fewer transistors and capacitors, and the gate drive circuit including the shift register unit only requires fewer clock signals. Therefore, the present disclosure may reduce the wiring area of the shift register unit and the gate drive circuit having the shift register units, and provide technical support for achieving the display panel with higher resolution and narrower frame. Meanwhile, the structures of the shift register unit and the gate drive circuit having the shift register units are simplified, thus simplifying the preparation process, and squeezing the preparation cost.

The present disclosure has been described by the above related exemplary embodiment, while the above embodiment is only an example of implementing the present disclosure. It should be pointed out that the disclosed embodiment does not limit the scope of the present disclosure. Instead, changes or modifications without departing from the spirit and scope of the present disclosure all belong to the patent protection scope of the present disclosure.

### DESCRIPTION OF REFERENCE NUMERALS

T1-T7: the first to seventh transistor
C1: the first capacitor
C2: the second capacitor
CK1: the first clock signal
CK2: the second clock signal
CK3: the third clock signal
VDD: the first voltage
VEE: the second voltage
VIN: the signal input end
VOUT: the signal output end
N1: the first node
N2: the second node
SR1: the first shift register unit
SR2: the second shift register unit
SR3: the third shift register unit
SR4: the fourth shift register unit

What is claimed is:

1. A shift register unit, comprising: a first to sixth transistor and a first and second capacitor, wherein:
a control end and a first end of the first transistor are coupled with a signal input end, and a second end of the first transistor is coupled with a first node;
a control end of the second transistor is coupled with a first clock signal, a first end of the second transistor is coupled with a first voltage, and a second end of the second transistor is coupled with the first node;
a control end of the third transistor is coupled with the first node, a first end of the third transistor is coupled with the first voltage, and a second end of the third transistor is coupled with a second node;
a control end of the fourth transistor is coupled with the first clock signal, a first end of the fourth transistor is coupled with a second voltage, and a second end of the fourth transistor is coupled with the second node;
a control end of the fifth transistor is coupled with the second node, a first end of the fifth transistor is coupled with the first voltage, and a second end of the fifth transistor is coupled with a signal output end;
a control end of the sixth transistor is coupled with a first end of the second capacitor, a first end of the sixth transistor is coupled with a second clock signal, and a second end of the sixth transistor is coupled with the signal output end;
a first end of the first capacitor is coupled with the first voltage, and a second end of the first capacitor is coupled with the second node; and
the first end of the second capacitor is coupled with the first node, and a second end of the second capacitor is coupled with the signal output end.

2. The shift register unit according to claim 1, wherein, the shift register unit further comprises a seventh transistor,
a control end of the seventh transistor is coupled with the second voltage, a first end of the seventh transistor is coupled with the first node, and a second end of the seventh transistor is coupled with the first end of the second capacitor.

3. The shift register unit according to claim 1, wherein, a phase of the first clock signal is ahead of the second clock signal by ⅔ of a signal period.

4. The shift register unit according to claim 1, wherein, all the transistors are P-type transistors.

5. The shift register unit according to claim 1, wherein, all the transistors are N-type transistors.

6. The shift register unit according to claim 1, wherein, the first voltage is a high level, and the second voltage is a low level.

7. The shift register unit according to claim 1, wherein, duty cycles of the low levels of the first clock signal and the second clock signal are both 1:3.

8. A gate drive circuit, comprising the shift register unit according claim 1.

9. The gate drive circuit according to claim 8, wherein, the gate drive circuit comprises a plurality of cascaded shift register units, except for the last level shift register unit, signal output ends of each level shift register unit are all coupled with signal input ends of the next level shift register unit, and a signal input end of the first level shift register is connected with an initial signal.

10. The gate drive circuit according to claim 9, wherein, the plurality of cascaded shift register units at least comprise a first shift register unit, a second shift register unit and a third shift register unit,
a signal output end of the first shift register unit is coupled with a signal input end of the second shift register unit, and
a signal output end of the second shift register unit is coupled with a signal input end of the third shift register unit.

11. The gate drive circuit according to claim 10, wherein, the gate drive circuit further comprises a clock signal generation unit, for generating a first clock signal, a second clock signal and a third clock signal whose phases are different form each other by ⅔ of a signal period,
the first clock signal in the first shift register unit is the first clock signal generated by the clock signal generation unit, and the second clock signal in the first shift register unit is the second clock signal generated by the clock signal generation unit,
the first clock signal in the second shift register unit is the third clock signal generated by the clock signal generation unit, and the second clock signal in the second shift register unit is the first clock signal generated by the clock signal generation unit, and
the first clock signal in the third shift register unit is the second clock signal generated by the clock signal generation unit, and the second clock signal in the third shift register unit is the third clock signal generated by the clock signal generation unit.

12. A display panel, comprising the gate drive circuit according to claim 8.
